(19) United States
(12) Patent Application Publication
(10) Pub. No.: US 2021/0212236 A1
(43) Pub. Date: Jul. 8, 2021

(54) PHASE-CHANGE MECHANICALLY DEFORMABLE COOLING DEVICE

(71) Applicants: Stephen Sang Geun OH, Songpa-Gu, Seoul (KR); Ki-Yong LEE, Seoul (KR)

(72) Inventors: Stephen Sang Geun OH, Songpa-Gu, Seoul (KR); Ki-Yong LEE, Seoul (KR)

(21) Appl. No.: 17/057,167

(22) PCT Filed: Mar. 15, 2019
(86) PCT No.: PCT/KR2019/003034

§ 371 Date: Nov. 20, 2020

(30) Foreign Application Priority Data
May 21, 2018 (KR) 10-2018-0057875

(51) Int. Cl. H05K 7/20; F28F 13/00

(52) U.S. Cl. CPC H05K 7/2029; F28D 2021/0029; F28F 13/00

(57) ABSTRACT

The present invention comprises: a base receiving heat from a heat source; a hollow cylinder-shaped fixed cylinder fixedly receiving the heat from the base, an opening thereof being closed by the base; fixed fins fixedly provided at the fixed cylinder to receive the heat from the fixed cylinder; a piston slidably blocking the inside of the fixed cylinder forming an accommodation chamber for a phase change material; and an elastic member for applying force toward the base with respect to the piston, wherein at low temperature heat, the phase change material changes a phase in a volume reducing direction, and the piston is returned to a backward position at the side of the base, and at high temperature heat, the phase change material changes the phase in a volume increasing direction, and the piston is operated to move from the backward position to a forward position.

### TECHNICAL FIELD

The present invention relates to a phase-change mechanically deformable cooling device, and more particularly, to a cooling device which is mechanically deformed in shape according to the contraction and expansion of a phase change material provided therein.

### BACKGROUND ART

In general, a cooling device is a device that cools the temperature of a target device. The target device may include not only electrical and electronic devices such as semiconductors, solar power panels, and electric motors, but also internal combustion engines, air conditioner outdoor units, etc. The cooling of the temperature is a concept including not only lowering a current temperature, but also maintaining the current temperature, suppressing an increase in the current temperature, or reducing or maintaining an increase rate.

In general, the cooling device may be provided in the form of a heat dissipation device, for example, a heat dissipation plate, which may include heat dissipation fins. The heat dissipation fin is a mechanism for increasing a surface area through which heat absorbed from a heat source may be dissipated. The heat dissipation device is made of a material having excellent thermal conductivity. As such a material, a metal such as gold, silver, platinum, copper or aluminum, or an alloy thereof, a composite material such as thermally conductive silicon, and the like may be used. In addition, the entire heat dissipation device may be made of these materials, and even if only a surface thereof is coated with these materials, in some cases, there is a practical effect. For example, in the case of the aluminum coating, AL6061 having thermal conductivity of 167 W/m·K or AL6101 having thermal conductivity of 218 W/m·K may be used.

The heat dissipation device or the heat dissipation plate, the heat dissipation fins, etc. may be formed in lines, surfaces, or three-dimensional shapes, and may be formed, for example, in a honeycomb shape. The heat dissipation fins are mounted either directly to a base that is thermally in contact with a heat source to absorb heat, or indirectly via an intermediate heat transfer member such as a column.

Meanwhile, a heat dissipation plate containing a phase change material (PCM) has been known. The heat dissipation plate uses latent heat, in which the phase change material absorbs heat. Accordingly, when heat from the heat source is absorbed through the base, this heat is not only dissipated to an atmosphere through the heat dissipation fins directly through the column, etc., but also this heat is absorbed while being used as latent heat for a phase change of the phase change material accommodated in an accommodation space provided inside the column, etc., and thus, a heat treatment effect is increased.

Here, the phase change material needs to be accommodated by filling this accommodation space as tightly as possible. For example, when an air layer is formed, heat transfer from a structure surrounding the accommodation space to the phase change material is not properly performed, and thus, there is a concern that heat dissipation performance is deteriorated.

However, in the phase change material, when the phase is changed due to the phase change, the volume thereof is changed. For example, when the phase change material changes a phase from solid to liquid due to heat absorption, the volume thereof is increased by about 10% to 15%, and when the phase is changed from liquid to gas, the volume thereof is increased by several to several tens of times. Therefore, if this accommodation space has a fixed internal space, there is a concern about leakage of the phase change material. Therefore, elasticity is required in this accommodation space.

In the related art, as in the following Patent Document, there is known a technique in which the volume of the accommodation space is increased or decreased according to the volume increased or decreased due to a phase change. This technique discloses ‘a volume-variable heat dissipation plate as a heat dissipation plate 100 comprising a base plate 10 that transfers heat generated from a heat source to a phase change material by contacting at least a part of a lower surface thereof with the heat source, a phase change material accommodation case 20 that is formed on the upper part of the base plate spaced at a predetermined interval in an inner direction from an outer edge of the base plate to accommodate the phase change material in the inner space thereof, and a heat dissipation case 30 in which an inner side of a body is coupled to an outer side of the phase change material accommodation case so as to be slidable in a vertical direction and a plurality of heat dissipation fins are formed on the top thereof, wherein at least two side points of the heat dissipation case body which are symmetrical to each other and an upper surface point of the base plate facing each other in a lower diagonal direction of the side points are connected to each other by an elastic member having a tensile property’.

In the heat dissipation plate of this Patent Document, a space in which the phase change material is accommodated is formed by an accommodation case and a heat dissipation case that slide in a vertical direction, and the base plate and the heat dissipation case coupled with the accommodation case are connected to each other by a tension-type elastic member. Accordingly, when the volume of the phase change material is increased by heat absorption, the accommodation case and the heat dissipation case are moved relative to each other in a separated direction against the elastic force of the elastic member to increase the accommodating space of the phase change material. In addition, when the volume of the phase change material is reduced by heat dissipation, the accommodation case and the heat dissipation case are moved relative to each other in an approached direction by the elastic force of the elastic member to reduce the accommodating space of the phase change material. Therefore, the leakage of the phase change material is prevented.

### PRIOR ART DOCUMENT

### Patent Document

Korean Patent Registration No. 10-0946406

### DISCLOSURE

### Technical Problem

The technology of the Patent Document is configured so that the accommodation case and the heat dissipation case are watertightly fitted to be approached to each other or separated from each other in a vertical direction. However, since the base plate is provided in contact with the target device of the heat source, the base plate is fixed, and the accommodation case is fixedly provided in the base plate. Accordingly, it can be seen that a fixed part is the base plate and the accommodation case, and a movable part is the heat dissipation case. In addition, the heat dissipation fins for dissipating heat to the atmosphere are provided in the heat dissipation case.

However, heat is transferred to the accommodation case through the base plate and this heat is transferred to the heat dissipation case and then dissipated to the atmosphere through the heat dissipation fins, but the accommodation case and the heat dissipation case are slidably moved relative to each other in a vertical direction and a sealing ring such as an O ring is interposed therebetween. Accordingly, a heat transfer blocking phenomenon occurs in which the heat is not smoothly transferred from the accommodation case to the heat dissipation case, so that the heat is not dissipated to the atmosphere through the heat dissipation fins or the efficiency is reduced.

In addition, since the heat dissipation fins are provided in a fixed form, there is a problem in that heat exceeding a designed heat capacity cannot be treated.

The present invention is to solve the problems in the related art and to provide a phase-change mechanically deformable cooling device, in which heat from a base provided to receive the heat from a heat source is transferred to fixed heat dissipation fins (fixed fins) fixedly provided to a fixed cylinder fixedly provided to the base in a structure where a volume of an internal space of an accommodation chamber for accommodating a phase change material is variable according to a phase change, thereby preventing a heat transfer blocking phenomenon and improving heat transfer efficiency.

Further, the present invention is to provide a phase-change mechanically deformable cooling device, in which additional movable heat dissipation fins (movable fins) are configured to protrude to and be returned from an atmosphere side by a variable part (piston) of which a position is changed according to a volume change of a phase change material expanded and contracted by heat from the heat source and an elastic member while maintaining heat transfer by a sliding contact part (heat transfer deformation part), wherein when the heat from the heat source is in low temperature, the movable fins are returned to a backward position (original position) by the elastic restoring force of the elastic member to minimize the exposure of the movable fins to the atmosphere, and when the heat from the heat source is in high temperature, the movable fins protrude from the backward position to a forward position against the elastic restoring force of the elastic member to maximize the atmosphere exposure, thereby adjusting the atmosphere exposure degree of the heat dissipation fins according to a heat load.

Further, the present invention is to provide a phase-change mechanically deformable cooling device, in which a contact part protruding and returned in connection with a variable part is configured to be in contact with and separated from a contact switch by the variable part (piston) of which a position is changed according to a volume change of a phase change material expanded and contracted by heat from the heat source and an elastic member, wherein when the heat from the heat source is in low temperature, the contact part is returned to a backward position by the elastic restoring force of the elastic member to release the contact of the contact part to the contact switch, and when the heat from the heat source is in high temperature, the contact part protrudes from the backward position to a forward position against the elastic restoring force of the elastic member to form a contact of the contact part to the contact switch, thereby adjusting the contact and the release of the contact part to the contact switch according to a heat load.

### Technical Solution

In order to achieve the objects, a phase-change mechanically deformable cooling device of the present invention comprises: a base provided so as to receive heat from a heat source; a hollow cylinder-shaped fixed cylinder fixedly provided so as to receive the heat from the base, and provided such that an opening thereof is closed by the base; fixed fins fixedly provided at the fixed cylinder so as to receive the heat from the fixed cylinder; a piston blocking the inside of the fixed cylinder in a watertight or airtight manner in a direction perpendicular to an axial direction, and fitted to be slidable in the axial direction so as to form an accommodation chamber for accommodating a phase change material; and an elastic member for applying an elastic restoring force toward the base with respect to the piston, wherein when the heat from the heat source is in low temperature, the phase change material changes a phase in a direction in which the volume thereof is reduced, and the piston is returned to a backward position at the side of the base by the elastic restoring force of the elastic member, and when the heat from the heat source is in high temperature, the phase change material changes the phase in a direction in which the volume thereof is increased, and the piston is operated so as to move from the backward position to a forward position at the opposite side of the base against the elastic restoring force of the elastic member.

The phase-change mechanically deformable cooling device may further comprise: an opening formed at an end of the fixed cylinder at the opposite side to the base; a protruding rod provided on a side of the piston facing the opening to pass through the opening; a heat transfer deformation part which is fixed to the protruding rod to deform a shape, a posture, or a position according to the movement of the protruding rod and provided in contact with the fixed cylinder so as to transfer the heat from the fixed cylinder; and movable fins fixedly provided in the heat transfer deformation part so as to transfer the heat from the heat transfer deformation part, wherein when the heat from the heat source is in low temperature, the phase change material changes a phase in the direction in which the volume thereof is reduced, the piston is returned to the backward position by the elastic restoring force of the elastic member, and then, the heat transfer deformation part and the movable fins fixed to the protruding rod are deformed to the shape, the posture, or the position corresponding to the backward position to minimize the atmosphere exposure and the air contact of the movable fins, and when the heat from the heat source is in high temperature, the phase change material changes the phase in the direction in which the volume thereof is increased, the piston is moved from the backward position to the forward position against the elastic restoring force of the elastic member, and then, the heat transfer deformation part and the movable fins fixed to the protruding rod are deformed to the shape, the posture, or the position corresponding to the forward position to maximize the atmosphere exposure and the air contact of the movable fins, thereby operating so that the atmosphere exposure degree of the movable fins is adjusted according to a heat load.

The phase-change mechanically deformable cooling device may further comprise: a contact part provided at a front end of the protruding rod moved forward and backward by the piston or the heat transfer deformation part or the movable fins, wherein when the heat from the heat source is in low temperature, the phase change material changes a phase in the direction in which the volume thereof is reduced, the contact part is returned to the backward position by the elastic restoring force of the elastic member, and then, the contact of the contact part to an external contact switch is released, and when the heat from the heat source is in high temperature, the phase change material changes the phase in the direction in which the volume thereof is increased, the contact part is returned from the backward position to the forward position against the elastic restoring force of the elastic member, and then, the contact of the contact part to the external contact switch is formed, thereby operating so that the contact and release of the contact part to the external contact switch are adjusted according to a heat load.

### Advantageous Effects

According to the present invention, there is provided a phase-change mechanically deformable cooling device in which heat from a base provided to receive the heat from a heat source is transferred to fixed heat dissipation fins (fixed fins) fixedly provided to a fixed cylinder fixedly provided to the base in a structure where a volume of an internal space of an accommodation chamber for accommodating a phase change material is variable according to a phase change, thereby preventing a heat transfer blocking phenomenon and improving heat transfer efficiency. Since the movable part is limited to the piston and the fixed fins are provided in the fixed part, a cooling effect by the fixed fins is secured by reliable heat transfer.

Further, according to the present invention, there is provided a phase-change mechanically deformable cooling device, in which additional movable heat dissipation fins (movable fins) are configured to protrude to and be returned from an atmosphere side by a variable part (piston) of which a position is changed according to a volume change of a phase change material expanded and contracted by heat from the heat source and an elastic member while maintaining heat transfer by a sliding contact part (heat transfer deformation part), wherein when the heat from the heat source is in low temperature, the movable fins are returned to a backward position (original position) by the elastic restoring force of the elastic member to minimize the exposure of the movable fins to the atmosphere, and when the heat from the heat source is in high temperature, the movable fins protrude from the backward position to a forward position against the elastic restoring force of the elastic member to maximize the atmosphere exposure, thereby adjusting the atmosphere exposure degree of the heat dissipation fins according to a heat load. Depending on the heat source, in addition to the fixed fins, the forward and backward movement of the movable fins is automatically operated, so that a constant and reliable cooling effect is expected.

Further, according to the present invention, there is provided a phase-change mechanically deformable cooling device in which a contact part protruding and returned in connection with a variable part is configured to be in contact with and separated from a contact switch by the variable part (piston) of which a position is changed according to a volume change of a phase change material expanded and contracted by heat from the heat source and an elastic member, wherein when the heat from the heat source is in low temperature, the contact part is returned to a backward position by the elastic restoring force of the elastic member to release the contact of the contact part to the contact switch, and when the heat from the heat source is in high temperature, the contact part protrudes from the backward position to a forward position against the elastic restoring force of the elastic member to form a contact the contact part to the contact switch, thereby adjusting the contact and the release of the contact part to the contact switch according to a heat load.

### DESCRIPTION OF DRAWINGS

FIGS. 1A and 1B are a perspective view and a top view of a phase-change mechanically deformable cooling device according to an embodiment of the present invention, respectively.

FIG. 2 is an exploded perspective view of the phase-change mechanically deformable cooling device of FIG. 1.

FIGS. 3A and 3B are perspective views of the phase-change mechanically deformable cooling device of FIG. 1 when contracting and expanding, respectively.

FIGS. 4A and 4B are side views of the phase-change mechanically deformable cooling device of FIG. 1 when contracting and expanding, respectively.

FIGS. 5A and 5B are cross-sectional views taken along the line A-A of the phase-change mechanically deformable cooling device of FIG. 1 when contracting and expanding, respectively.

### BEST MODE

Hereinafter, a phase-change mechanically deformable cooling device according to the present invention will be described in detail with reference to the accompanying drawings. However, with respect to members having the same function by the same configuration, the detailed description may be omitted by maintaining the same reference numerals even if the drawings are varied.

In addition, a relationship in which other members are arranged or connected to front, rear, left, right, upper, or lower sides of any member includes a case where another member is interposed therebetween. On the contrary, when any member is disposed ‘directly’ on front, rear, left, right, upper, or lower sides of another member, it is meant that there is no separate member therebetween. In addition, when any part ‘comprises’ other components, unless stated explicitly otherwise, it is meant that other components may be further included without excluding other components.

In addition, dividing names of components into first, second, and the like is to divide the names because the components are the same in configuration as each other, and an order thereof is not particularly limited. In addition, the terms such as ‘unit’, ‘means’, ‘part’, and ‘member’, which are described in the specification, mean units of a comprehensive configuration that performs at least one function or operation.

In addition, since the size and thickness of each configuration illustrated in the drawings are arbitrarily shown for convenience of description, the present invention is not necessarily limited to those illustrated in the drawings, and in order to clearly express various parts and areas, such as layers and areas, the thickness, and the like may be exaggerated to be expanded or reduced.

<Basic Configuration—Fixed Fins Directly Provided to Fixed Part>

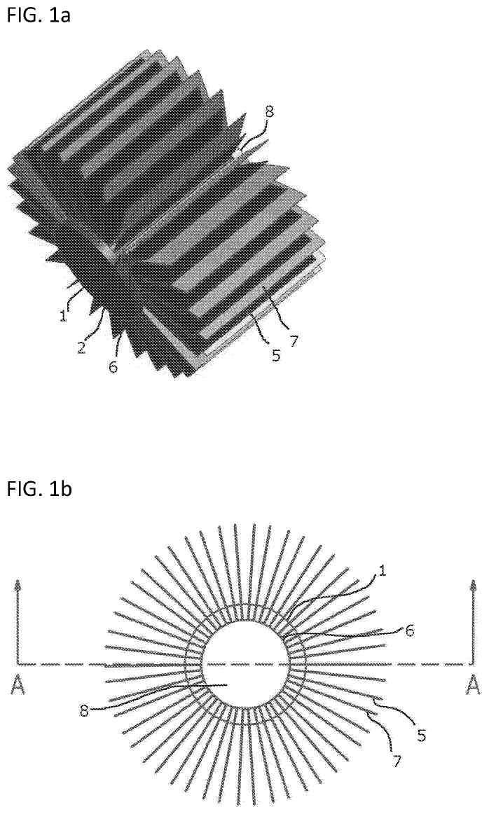

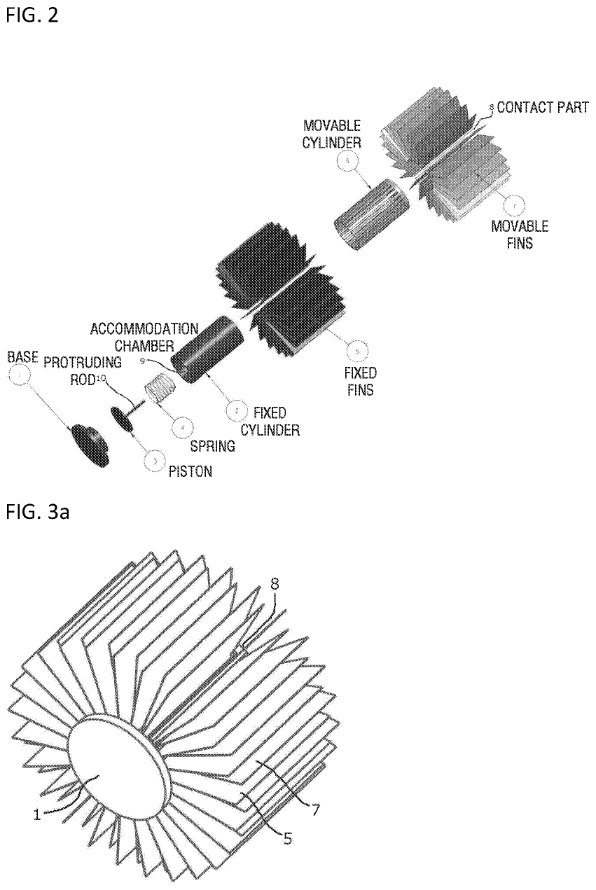

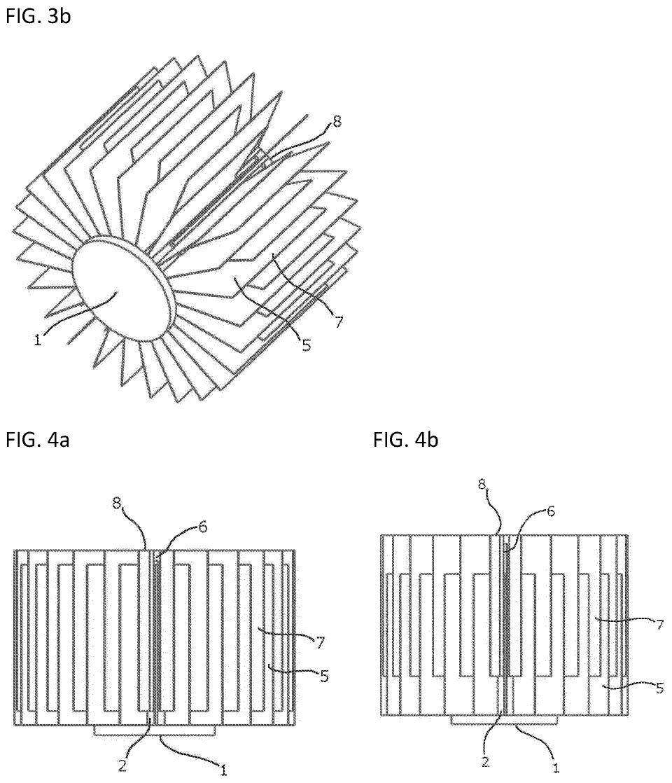

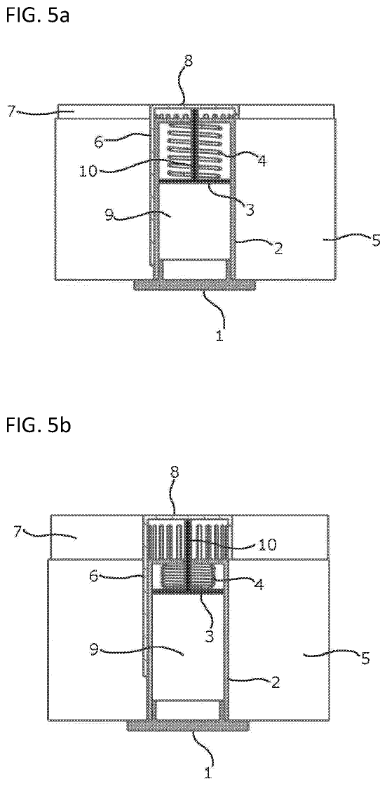

A phase-change mechanically deformable cooling device according to an embodiment of the present invention is a cooling device which is mechanically deformed according to the contraction and expansion of a phase change material provided therein. As illustrated in FIGS. 1 to 5, the phase-change mechanically deformable cooling device comprises a base 1, a fixed cylinder 2, fixed fins 5, a piston 3, and an elastic member 4.

The base 1 is a member provided to receive heat from a heat source (not illustrated). The cooling device is a device that cools the temperature of a target device, and the heat source may be acquired from devices including internal combustion engines, air conditioner outdoor units, etc. as well as electrical and electronic devices such as semiconductors, solar power panels, and electric motors, which are target devices. The base 1 may be directly connected to the heat source by itself, or may be connected to the heat source through a separate member, for example, a separate heat transfer cream, a heat transfer plate, a heat sink, or the like interposed therebetween.

The fixed cylinder 2 is a hollow cylinder-shaped cylinder fixedly provided to receive the heat from the base 1 and provided so that an opening thereof is closed by the base 1. While the opening is closed by the base 1, the fixed cylinder 2 provides a space which accommodates the piston 3 and the elastic member 4 to be described below and is to be formed as a variable accommodation chamber for the phase change material.

The fixed fins 5 are heat dissipation fins which are fixedly provided on the fixed cylinder 2 to receive the heat from the fixed cylinder 2. The heat applied to the base 1 is transferred to the fixed fins 5 through the fixed cylinder 2 and discharged from the fixed fins 5 to the atmosphere.

The piston 3 is a member which blocks the inside of the fixed cylinder 2 in a watertight or airtight manner in a direction perpendicular to an axial direction and is slidably fitted in the axial direction to form an accommodation chamber 9 for accommodating the phase change material. The piston 3 is formed in a flat disk shape having a predetermined thickness for sliding with watertightness or airtightness. The internal space of the fixed cylinder 2 is divided into two portions by the piston 3, wherein the space on the base 1 side becomes the accommodation chamber 9, and the space on the opposite side of the base 1 becomes a space in which the elastic member 4 to be described below is accommodated.

The elastic member 4 is a member that applies an elastic restoring force toward the base with respect to the piston 3. As the elastic member 4, a material or member having elasticity, such as a spring, rubber, or silicone may be used.

Here, since the base 1, the fixed cylinder 2, and the fixed fins 5 are all fixedly connected to each other, the base 1, the fixed cylinder 2, and the fixed fins 5 become a fixed, constant and reliable path for heat transfer. Therefore, uniformity in cooling treatment performance is ensured.

In addition, as materials therefor, materials having excellent thermal conductivity and excellent contact retention, for example, metals such as gold, silver, platinum, copper or aluminum or alloys thereof, and synthetic materials such as thermally conductive silicon may be used. In addition, the base 1, the fixed cylinder 2, and the fixed fins 5 may be entirely made of these materials, and even if only the surfaces thereof are coated with these materials, in some cases, there is a practical effect. For example, in the case of the aluminum coating, AL6061 having thermal conductivity of 167 W/m·K or AL6101 having thermal conductivity of 218 W/m·K may be used.

In the phase-change mechanically deformable cooling device according to an embodiment of the present invention, when the heat from the heat source is in low temperature, the heat is transferred in the order of the base 1, the fixed cylinder 2, and the fixed fins 5 to be discharged to the atmosphere, and as a result, the phase change material changes a phase in a direction in which the volume thereof is reduced by removing the heat and the piston 3 is returned to a backward position toward the base 1 by the elastic restoring force of the elastic member 4. Meanwhile, when the heat from the heat source is in high temperature, even though some heat is transferred in the order of the base 1, the fixed cylinder 2, and the fixed fins 5 to be discharged to the atmosphere, heat treatment is insufficient, and the remaining heat is applied from the base 1 to the phase change material in the accommodation chamber 9, and as a result, the phase change material changes the phase in a direction in which the volume thereof is increased while heat energy is consumed by the phase change and the piston 3 is operated to move from the backward position to a forward position of the opposite direction of the base 1 against the elastic restoring force of the elastic member 3 by the pressure by the increased volume of the phase change material.

<Effects>

According to the phase-change mechanically deformable cooling device according to an embodiment of the present invention having the above configuration, the phase change material may be filled in the accommodation chamber without an air layer. Therefore, there is an effect of maximizing the heat conduction efficiency.

In addition, even when the phase change material changes a phase in the direction in which the volume thereof is increased, the increased volume may be absorbed by the forward movement of the piston. Therefore, there is an effect of preventing leakage of the phase change material from the accommodation chamber.

In addition, even when the phase change material changes the phase in the direction in which the volume thereof is reduced, the reduced volume may be absorbed by the backward movement of the piston. Accordingly, there is an effect of preventing the formation of the air layer in the accommodation chamber to maintain the heat conduction efficiency to the maximum.

In addition, since the base 1, the fixed cylinder 2, and the fixed fins 5 are all fixedly connected to each other, there is an effect of preventing incomplete heat transfer or a heat transfer blocking phenomenon to ensure a fixed, constant and reliable path for heat transfer.

<Movable Fins for Increasing or Decreasing Heat Dissipation According to Heat Capacity>

A phase-change mechanically deformable cooling device according to another embodiment of the present invention further comprises an opening, a protruding rod 10, a heat transfer deformation part 6, and movable fins 7.

The opening is a hole formed at an end of the fixed cylinder 2 at the opposite side to the base 1. The surface of the piston 3 at the opposite side to the base 1 or the elastic member 4 may be in contact with an external atmosphere through the opening.

The protruding rod 10 is a member provided on a side of the piston 3 facing the opening to pass through the opening. The protruding rod 10 transmits the forward and backward movement of the piston 3 to the outside of the fixed cylinder 2.

The heat transfer deformation part 6 is a member which is fixed to the protruding rod 10 to deform a shape, a posture, or a position according to the movement of the protruding rod 10 and provided in contact with the fixed cylinder 2 so as to transfer the heat from the fixed cylinder 2.

As illustrated in the drawing, the heat transfer deformation part 6 may be provided in the form of a movable cylinder fitted between the fixed fins 5 provided on an outer periphery of the fixed cylinder 2. As a result, the heat transfer deformation part 6 slides in accordance with the forward and backward movement of the protruding rod 10 while being fitted to the outer periphery of the fixed cylinder 2, so that the position thereof can be moved forward and backward.

However, the present invention is not limited to the illustrated example, and if a configuration satisfies both a heat transfer function by contact and a deformation function of shape deformation according to the forward and backward movement of the protruding rod 10, for example, deformation of a shape, a posture, and a position, various modifications are possible.

For example, the heat transfer deformation part 6 may be formed in a shape of shape or posture-deformable arms in the same manner of spreading the movable fins according to the forward movement of the protruding rod 10 and accommodating the movable fins according to the backward movement of the protruding rod 10. At this time, the arms may be configured to be operated through a hinge fixed to the fixed cylinder.

The movable fins 7 are heat dissipation fins which are fixedly provided on the heat transfer deformation part 6 to receive the heat from the heat transfer deformation part 6. By the movable fins 7, the heat capacity limited to the surface area of the fixed fins 5 may be increased.

In addition, when the heat from the heat source is in low temperature, when the heat is transferred and treated in the order of the base 1, the fixed cylinder 2, and the fixed fins 5, the phase change material changes a phase in the direction in which the volume thereof is reduced, the piston 3 is returned to the backward position by the elastic restoring force of the elastic member 4. Accordingly, the shape, the posture, or the position of the heat transfer deformation part 6 and the movable fins 7 fixed to the protruding rod 10 is deformed to correspond to the backward position to minimize the atmosphere exposure and the air contact of the movable fins 7. When the heat from the heat source is in high temperature, even though some heat is transferred and treated in the order of the base 1, the fixed cylinder 2, and the fixed fins 5, the phase change material absorbs the remaining heat to be used for the phase change, and as a result, the phase change material changes the phase in the direction in which the volume thereof is increased and the piston 3 is moved from the backward position to the forward position against the elastic restoring force of the elastic member 4 according to the pressure by the increased volume. Accordingly, the shape, the posture, or the position of the heat transfer deformation part 6 and the movable fins 7 fixed to the protruding rod 10 is deformed to correspond to the forward position to maximize the atmosphere exposure and the air contact of the movable fins 7. Therefore, the movable fins 7 are operated so that the atmosphere exposure degree of the movable fins 7 is adjusted according to a heat load.

According to the embodiment, when the heat is in low temperature, the atmosphere exposure and the air contact of the movable fins 7 are minimized to prevent damage caused by supercooling, and when the heat is in high temperature, the atmosphere exposure and the air contact of the movable fins 7 are maximized to additionally secure the cooling performance.

<Contact Part Used for Control According to Heat Capacity>

A phase-change mechanically deformable cooling device according to yet another embodiment of the present invention further comprises a contact part 8 provided at a front end of the protruding rod 10 moved forward and backward by the piston 3 or the heat transfer deformation part 6 or the movable fins 7. The contact part 8 may be made of a material that blocks heat transfer to an external contact switch (not illustrated).

This external contact switch may be provided near a portion of the target device facing the contact part 8 of the cooling device of the present invention, and an on/off signal of this contact switch is input to, for example, a controller or may be used for a subsequent control, for example, whether a forced blower fan is operated or whether a high temperature alarm is performed.

In addition, when the heat from the heat source is in low temperature, the heat is transferred in the order of the base 1, the fixed cylinder 2, and the fixed fins 5 to be discharged to the atmosphere, and as a result, the phase change material changes a phase in the direction in which the volume thereof is reduced by removing the heat, the contact part 8 is returned to the backward position as the piston is moved to the backward position by the elastic restoring force of the elastic member 4, and then the contact of the contact part 8 to the external contact switch (not illustrated) is released. When the heat from the heat source is in high temperature, even though some heat is transferred in the order of the base 1, the fixed cylinder 2, and the fixed fins 5 to be discharged to the atmosphere, heat treatment is insufficient, and the remaining heat is applied from the base 1 to the phase change material in the accommodation chamber 9, and then, as the piston is moved to the forward position while heat energy is consumed by the phase change, the contact part 8 protrudes from the backward position to forward position against the elastic restoring force of the elastic member 4 to form the contact of the contact part 8 to the external contact switch (not illustrated). Therefore, the contact part 8 is operated so that the contact and release of the contact part 8 to the external contact switch (not illustrated) are adjusted according to a heat load.

As a result, whether the heat source is in high or low temperature is converted into mechanical deformation, and such mechanical deformation can be used for a subsequent control through on/off of the contact switch.

While the preferred embodiments of the present invention have been described above, the present invention is not limited to the above-described embodiments, and may be implemented by modifications in various forms within the scope of appended claims, the detailed description of the invention, and the accompanying drawings, and other equivalent embodiments are possible. It is natural to those skilled in the art that the modifications and equivalent embodiments which belong to the scope of the present invention, and only the embodiments are provided to complete the disclosure of the present invention and to fully inform the scope of the present invention to those skilled in the art to which the present invention belongs, and the present invention is only defined by the scope of the appended claims.

### INDUSTRIAL APPLICABILITY

The present invention can be used in the industry of a phase-change mechanically deformable cooling device.

### EXPLANATION OF REFERENCE NUMERALS AND SYMBOLS

1: Base
2: Fixed cylinder
3: Piston
4: Elastic member (spring)
5: Fixed fins (heat dissipation fins)
6: Movable cylinder
7: Movable fins (heat dissipation fins)
8: Contact part
9: Accommodation chamber
10: Protruding rod

1. A phase-change mechanically deformable cooling device comprising:
a base provided so as to receive heat from a heat source;
a hollow cylinder-shaped fixed cylinder fixedly provided so as to receive the heat from the base, and provided such that an opening thereof is closed by the base;
fixed fins fixedly provided at the fixed cylinder so as to receive the heat from the fixed cylinder;
a piston blocking the inside of the fixed cylinder in a watertight or airtight manner in a direction perpendicular to an axial direction, and fitted to be slidable in the axial direction so as to form an accommodation chamber for accommodating a phase change material;
an elastic member for applying an elastic restoring force toward the base with respect to the piston;
an opening formed at an end of the fixed cylinder at the opposite side to the base;
a protruding rod provided on a side of the piston facing the opening to pass through the opening;
a heat transfer deformation part which is fixed to the protruding rod to deform a shape, a posture, or a position according to the movement of the protruding rod and provided in contact with the fixed cylinder so as to transfer the heat from the fixed cylinder; and
movable fins fixedly provided in the heat transfer deformation part so as to transfer the heat from the heat transfer deformation part,
wherein when the heat from the heat source is in low temperature, the phase change material changes a phase in a direction in which the volume thereof is reduced, the piston is returned to a backward position at the side of the base by the elastic restoring force of the elastic member, and then, the heat transfer deformation part and the movable fins fixed to the protruding rod are deformed to the shape, the posture, or the position corresponding to the backward position to minimize the atmosphere exposure and the air contact of the movable fins, and
when the heat from the heat source is in high temperature, the phase change material changes the phase in a direction in which the volume thereof is increased, the piston is operated so as to move from the backward position to a forward position at the opposite side of the base against the elastic restoring force of the elastic member, and then, the heat transfer deformation part and the movable fins fixed to the protruding rod are deformed to the shape, the posture, or the position corresponding to the forward position to maximize the atmosphere exposure and the air contact of the movable fins,
thereby operating so that the atmosphere exposure degree of the movable fins is adjusted according to a heat load.

2. (canceled)

3. The phase-change mechanically deformable cooling device of claim 1, further comprising:
a contact part provided at a front end of the protruding rod moved forward and backward by the piston or the heat transfer deformation part or the movable fins,
wherein when the heat from the heat source is in low temperature, the phase change material changes a phase in the direction in which the volume thereof is reduced, the contact part is returned to the backward position by the elastic restoring force of the elastic member, and then, the contact of the contact part to an external contact switch is released, and
when the heat from the heat source is in high temperature, the phase change material changes the phase in the direction in which the volume thereof is increased, the contact part is returned from the backward position to the forward position against the elastic restoring force of the elastic member, and then, the contact of the contact part to the external contact switch is formed,
thereby operating so that the contact and release of the contact part to the external contact switch are adjusted according to a heat load.
